(19) United States
(12) Patent Application Publication
(10) Pub. No.: US 2017/0311469 A1
(43) Pub. Date: Oct. 26, 2017

(54) MOUNTED ENCLOSURE FOR COMMUNICATION COMPONENTS

(71) Applicant: William Carl Anderson, III, Dallas, TX (US)

(72) Inventor: William Carl Anderson, III, Dallas, TX (US)

(21) Appl. No.: 15/633,710

(22) Filed: Jun. 26, 2017

Related U.S. Application Data
(63) Continuation-in-part of application No. 15/498,387, filed on Apr. 26, 2017.
(60) Provisional application No. 62/354,569, filed on Jun. 24, 2016.
(60) Provisional application No. 62/327,960, filed on Apr. 26, 2016.

(51) Int. Cl. H05K 5/06; H05K 5/02

(52) U.S. Cl. CPC H05K 5/069; H05K 5/061; H05K 5/0217; H05K 5/0247

(57) ABSTRACT

In various implementations, an enclosure may be utilized to secure component(s) to location(s), such as an overhead portion of a structure (e.g., a ceiling) for a variety of applications, such as creating a communications network. For example, an enclosure may be utilized to secure communications component(s). The enclosure may include one or more finishing brackets, back members, mounting brackets, gaskets, and shells. One of more components of the enclosure may be coupled (e.g. via the gasket(s)) to create a seal that inhibits the components in the enclosure from being exposed to fluids and/or particles. The shell may not cause substantial signal loss, in some implementations.

### CROSS-REFERENCE TO RELATED APPLICATIONS

This application is a continuation in part of U.S. patent application Ser. No. 15/498,387, entitled “Enclosure for Electronic Components”, filed on Apr. 26, 2017, which claims the benefit of U.S. Patent Application Ser. No. 62/327,960, entitled “Enclosure for Communications Components”, filed on Apr. 26, 2016, both of which are hereby incorporated by reference for all purposes. This application also claims the benefit of U.S. Patent Application No. 62/354,569, entitled “Mounted Enclosure for Communication Components”, filed on Jun. 24, 2016, which is hereby incorporated by reference for all purposes.

### TECHNICAL FIELD

The present invention relates to mounted enclosures for communication components.

### BACKGROUND

Residential and commercial structures (e.g., buildings, pavilions, stadiums, etc.) may include communication wiring that is accessible at locations determined during construction. However, adding and/or rearranging communication equipment after the initial construction may be difficult. For example, since a cable may be needed at different locations than initially set locations, access hatches (e.g., a large hole in the ceiling through which a person has access) may be cut to pull cables and/or wiring to a location in which communication equipment will be installed. As another example, when new wiring is added to an existing structure, an access hatch may be cut in an existing ceiling and cable(s) may be dropped and/or pulled through the ceiling to bring the cable(s) to a location in which communication equipment will be installed. However, the access hatches may need to be separately installed and/or finished out from the communication equipment installation, which may increase costs, installation times, and/or maintenance (e.g., since access hatches may need to be cleaned, repainted, etc.).

### SUMMARY

In various implementations, an enclosure may be provided that houses components, such as communication components. The enclosure may be mounted on an elevated surface, such as a ceiling, in some implementations. The enclosure may include a finishing bracket, back member, and/or shell. Gasket(s) may be utilized to create a seal between the shell and the finishing bracket and/or between other combinations of components of the enclosure (e.g., to minimize entry of dust, fluids, etc.). One or more components (e.g., communication components) may be disposed in and/or coupled to the enclosure. In some implementations, a mounting bracket may be utilized to couple component(s) to the enclosure (e.g., since in overhead installations loose components may otherwise fall out or move in the enclosure).

In various implementations, the enclosure may protect components from the elements (e.g., fluids from rain and/or snow and/or debris, such as hail, etc.), other fluids (e.g., cleaning, spills, fire sprinklers, etc.), and/or other debris (e.g., dust) since powered components may be damaged by exposure to fluids and/or debris. For example, the shell and the mounting bracket and/or the mounting bracket and other component(s) of the enclosure may be coupled to create a seal that inhibits exposing the components to fluid (e.g., from precipitation, leaks, and/or spills) and/or debris (e.g., dust).

The enclosures may be utilized in a variety of applications such as to house components that deliver wireless signals to a plurality of locations, provide power to other components, etc.

In various implementations, an enclosure may be provided to house electrical components (e.g., communication components). The enclosure may include components such as a finishing bracket, a back member, a mounting bracket (e.g., a frame), and a shell. The components may be coupled together via fasteners. The finishing bracket may be directly coupleable to a ceiling and/or a wall (e.g., a portion of a ceiling and/or wall). The finishing bracket may include a first side proximate the ceiling and/or the wall upon installation, a second opposing side, and an opening disposed through the finishing bracket. The back member may include a body. At least a portion of the body may be disposed at least partially through the opening of the finishing bracket. A flange may extend from at least a portion of the body proximate an end of the body of the back member. The flange may include a first side, which is coupled to the second side of the finishing bracket, and an opposing second side. The flange may retain the back member to the finishing member. The mounting bracket may be coupled to the back member of the body. The mounting bracket may include a first side, which is coupled to a second side of the back member (e.g., coupled to the flange of the back member), a second opposing side, and an outer wall disposed between the first side and the second side. The mounting bracket may include a first recess disposed in the first side and a second recess disposed in the second side. The mounting bracket may include a first gasket disposed at least partially in the first recess, and a second gasket disposed at least partially in the second recess. Coupling the first side of the mounting bracket to the second side of the back member (e.g., via fasteners disposed through aligned openings in the mounting bracket and the back member) may compress the first gasket to create a first seal between the mounting bracket and the back member. The mounting bracket may include inner surface(s) disposed between the first recess and an edge of the first side and between the second recess and an edge of the second side and/or opposing outer surface(s) disposed between the first recess and the outer wall and between the second recess and the outer wall. The mounting bracket may include openings disposed in at least one of the outer surfaces. The openings may be disposed on outer surfaces (e.g., exterior to the gaskets) to inhibit leaks. The openings of the mounting bracket may be through the mounting bracket and capable of receiving a fastener to couple the mounting bracket to other components of the enclosure, such as the back member and/or the shell. The mounting bracket may be capable of coupling with one or more electronic components (e.g., directly and/or indirectly). The shell may be coupled to the second side of the mounting bracket such that components coupled to the mounting bracket are at least partially enclosed between the shell and the back member and such that the second gasket is at least partially compressed to form a seal between the shell and the mounting frame. For example, the shell and the mounting bracket may be coupled via fasteners disposed through aligned openings in the mounting bracket and the shell.

Implementations may include one or more of the following features. The enclosure may be water resistant upon assembly. The opening disposed through the finishing bracket may be disposed proximate the center of the finishing bracket. The opening may have a size large enough for a portion of a body, such as arms and/or head, of a user (e.g., an installer) to fit through the opening. The body of the back member may have an opening through which one or more cables (e.g., to be coupled to electrical components) may pass. The opening may or may not include gaskets and/or seals to inhibit debris and/or fluids from entering the back member and contacting the components. The second side of the back member may include a back recess capable of receiving the mounting bracket. The finishing bracket may include one or more finishing bracket openings and one or more first fasteners may be disposed at least partially through one or more of the finishing bracket openings to couple the finishing bracket to the ceiling and/or the wall. The first fasteners may include an anchor. The enclosure may include one or more component brackets capable of coupling with one or more electronic components and the mounting bracket. Component bracket(s) may be slidably coupled (e.g., such that a position of at least one component bracket is alterable) and/or fixedly coupled to the mounting bracket. The mounting bracket may include one or more chamfered corners, in some implementations. A chamfered corner may include at least two corners and an angled section disposed between at least two of the corners. Each of the corners may be a bend in the outer wall. In some implementations, a portion of a top section is removed such that the bend disposes a free edge of a first edge of the top section proximate to a free edge of the second edge of the top section in each of the corners and a portion of a bottom section is removed such that the bend disposes a free edge of a first edge of the bottom section proximate to a free edge of the second edge of the bottom section in each of the corners. The top section may be disposed on the first side and the bottom section may be disposed on the second side. The mounting bracket may include two or more slots disposed on an inner surface between the first side and the second side. The slots may be capable of receiving one or more component brackets. For example, the inner surfaces of the mounting bracket may include a first side and an opposing second side. At least one slot may be disposed along at least part of the first side of the inner surface and at least one slot may be disposed along at least part of a second side of the inner surfaces. One or more component brackets (e.g., capable of coupling with one or more electronic components) may be coupled to the mounting bracket via the slots of the mounting bracket. A component bracket may include first protrusion(s) and second protrusion(s). At least one of the first protrusions may be configured to be disposed in at least one of the slots disposed along a part of the first side of the inner surface of the mounting bracket and at least one of the second protrusions may be configured to be disposed in at least one of the slots disposed along a part of the second side of the inner surfaces to couple the component bracket to the body. The shell may be impact resistant.

In various implementations, an enclosure may house electrical components. The enclosure may be coupleable to at least a portion of a wall and/or ceiling. The enclosure may include a finishing bracket, back member, mounting bracket and shell. The finishing bracket may be directly coupleable to a ceiling and/or a wall. The finishing bracket may include a first side, which is proximate to the ceiling and/or wall upon installation, and a second opposing side. The finishing bracket may include an opening disposed through the finishing bracket (e.g., to allow access by users to an area behind the wall and/or ceiling). The back member may include a body that is capable of being disposed at least partially through the opening of the finishing bracket and a flange extending from at least a portion of the body proximate an end of the body of the back member. The flange may include a first side, which is coupleable to the second side of the finishing bracket, and an opposing second side. The mounting bracket may include a first side, which is coupleable to a second side of the back member; a second opposing side; and an outer wall disposed between the first side and the second side. The mounting bracket may include a recess (e.g., a second recess) disposed in the second side of the mounting bracket and capable of receiving at least a portion of a second gasket. Compression of the second gasket in the second recess may create a seal (e.g., to inhibit entry of debris and/or fluids). The mounting bracket may include openings through the mounting bracket and disposed between the outer wall and the second recess. Opening(s) may be capable of receiving a fastener to couple the mounting bracket to other components of the enclosure, such as the back member and/or shell. The mounting bracket may be capable of coupling with one or more electronic components (e.g., directly and/or indirectly via component brackets). The enclosure may include a shell coupled to the second side of the mounting bracket such that the one or more components coupled to the mounting bracket are at least partially enclosed between the shell and the back member. Coupling the shell to the mounting brackets may generate a force that at least partially compresses the second gasket in the recess of the mounting bracket to form a seal between the shell and the mounting frame.

Implementations may include one or more of the following features. In some implementations, one or more fasteners may be positioned in openings in the shell, mounting bracket, back member, finishing bracket, ceiling and/or wall to couple components together and/or to a ceiling and/or wall. The mounting bracket may include a first recess disposed in the first side and capable of receiving at least a portion of a first gasket. Coupling the first side of the mounting bracket to the second side of the back member (e.g., via fasteners disposed through aligned openings in the mounting bracket and the back member) may compresses the first gasket to create a first seal between the mounting bracket and the back member. Coupling the shell to the mounting bracket and back member (e.g., via fasteners disposed through aligned openings in the mounting bracket and the back member) may compress the first gasket to create a seal between the mounting bracket and the back member. The openings through the mounting bracket may be disposed between the first recess and the outer wall of the mounting bracket. The enclosure may be water resistant upon assembly. In some implementations, the second side of the back member may include a back recess that is capable of receiving the mounting bracket. In some implementations, the enclosure may include component bracket(s) slidably coupleable to the mounting bracket and/or component brackets fixedly coupleable to the mounting bracket. The component brackets may be capable of coupling with at least one electronic component. In some implementations, the component brackets may be pre-coupled with electrical component(s) (e.g., for ease of installation).

In various implementations, the enclosure may be installed in a portion of a wall and/or ceiling. A finishing bracket may be coupled to a surface (e.g., a ceiling and/or wall) via one or more first fasteners. The surface may include an outer side coupled to the finishing bracket and an inner side proximate an inner area (e.g., area behind a ceiling or wall). The first fastener(s) may be disposed in finishing bracket opening(s) in the finishing bracket. An orifice may be created (e.g., cut) in the surface using a second opening in the finishing bracket as a template. The second opening may have a size that allows at least a portion of a user (e.g., arms and/or head of a user) to pass through the second opening to the inner area. A back member may be disposed at least partially through the second opening in the finishing bracket and the orifice in the surface. The back member may be coupled to the finishing member, for example, via fasteners disposed through aligned openings in the back member and the finishing bracket. The fasteners may extend at least partially through the ceiling and/or wall, in some implementations. Component brackets may be coupled to a mounting bracket that is coupled to the back member. One or more electrical component may be coupled to each of the component brackets in the enclosure. The shell of the enclosure may be coupled to the surface (e.g., of the ceiling and/or wall) by coupling the shell to the mounting bracket. Coupling a shell to the mounting bracket may compress a first gasket disposed in a first recess of the mounting bracket and/or a second gasket disposed in a second recess of the mounting bracket. Compressing the first gasket and/or second gasket may create a seal (e.g., between the shell and the mounting bracket and/or the mounting bracket and the back member).

Implementations may include one or more of the following features. Coupling a finishing bracket to the surface may include: creating a set of first openings in the surface; and, disposing each of the first fasteners through one of the finishing bracket openings and through one of the first openings in the set of first openings in the surface such that a first anchor of the first fastener is disposed and retained in the first opening.

In some implementations, a mounting bracket may include a first side, which is coupled to a second side of the back member; a second opposing side; and an outer wall disposed between the first side and the second side. The mounting bracket may include: one or more inner surfaces disposed between the first recess and an edge of the first side and between the second recess and an edge of the second side; and, one or more opposing outer surfaces disposed between the first recess and the outer wall and between the second recess and the outer wall. Opening(s) may be disposed in at least one of the outer surfaces and through the mounting bracket, and each opening may receive a fastener to couple the mounting bracket to at least one of the back member or the shell. Coupling one or more component brackets to the mounting bracket may include slidably coupling at least one of the component brackets to the mounting bracket. Coupling the component bracket to the mounting bracket may include inserting protrusions of the component bracket into slots in the mounting bracket. The mounting bracket may be coupled to the back member via fasteners disposed through aligned openings in the mounting bracket and the back member and/or otherwise coupled to the back member (e.g., via affixing, bonding, etc). In some implementations, the back member may include a recess and the mounting bracket may be disposed in the recess. Electrical components may be coupled to component bracket(s) coupled to the mounting bracket.

The details of one or more implementations are set forth in the accompanying drawings and the description below. Other features, objects, and advantages of the implementations will be apparent from the description and drawings.

### BRIEF DESCRIPTION OF THE DRAWINGS

For a more complete understanding of this disclosure and its features, reference is now made to the following description, taken in conjunction with the accompanying drawings, in which:

FIG. 1A illustrates a perspective front view of an implementation of an example enclosure.

FIG. 1B illustrates an implementation of a portion of the example enclosure illustrated in FIG. 1A.

FIG. 1C illustrates an implementation of a portion of the example enclosure illustrated in FIG. 1A.

FIG. 1D illustrates an implementation of a portion of the example enclosure illustrated in FIG. 1A.

FIG. 1E illustrates an implementation of a portion of the example enclosure illustrated in FIG. 1A.

FIG. 1F illustrates an implementation of a portion of the example enclosure illustrated in FIG. 1A.

FIG. 1G illustrates an implementation of a portion of the example enclosure illustrated in FIG. 1A.

FIG. 1H illustrates an implementation of a portion of the example enclosure illustrated in FIG. 1A.

FIG. 1I illustrates an implementation of a portion of the example enclosure illustrated in FIG. 1A.

FIG. 2A illustrates a cross-section of an implementation of an example enclosure.

FIG. 2B illustrates an implementation of an example portion of an enclosure that includes a mounting bracket with chamfered corners.

FIG. 2C illustrates a portion of the implementation of the example mounting bracket illustrated in FIG. 2B.

FIG. 2D illustrates a top view of a portion of the example mounting bracket illustrated in FIG. 2C.

Like reference symbols in the various drawings indicate like elements.

### DETAILED DESCRIPTION

Enclosures (e.g., housings for components) may be used in a variety of applications, such as the deployment of, for example but not limited to, large-scale Wi-Fi systems. The enclosures may house various components, such as electrical components and/or other types of components. For example, electrical components may include communication components (e.g., RF and/or Wireless transmission equipment such as Wi-Fi access points, radio frequency base stations, remote units, zone components, optical network terminals, and/or other active RF related electronics; wired communication equipment; fiber optic communication equipment, such as a wireless access point, fiber optic converter, and/or connectors; converters; active antennae; passive antennae; and/or other appropriate types of communication equipment), sensors (e.g., temperature, vibration, noise, moisture, etc.), power supplies, and/or any other appropriate electronic component. The components can be positioned and/or secured in the enclosure. Since the enclosures are designed for use in communication networks, at least a portion of the enclosure must not inhibit communication with other devices. For example, the enclosure may not substantially reduce the ability of the wireless components to communicate with and/or receive communications from other devices. In some implementations, the enclosure may be a housing that is visually appealing and/or less visually obtrusive (e.g., to increase user satisfaction and/or to inhibit tampering).

In some implementations, since the enclosures may be used in communication networks, at least a portion of the enclosure may not inhibit communication with other devices. For example, the enclosure may not substantially reduce the ability of the wireless components to communicate with and/or receive communications from other devices. In some implementations, a portion of the enclosure may be made of a material that does not substantially inhibit communication to and/or receiving communication from other devices (e.g., proximate devices, devices in the same network, etc.).

In some implementations, the enclosure may be a housing that is visually appealing and/or less visually obtrusive (e.g., to increase user satisfaction and/or to inhibit tampering). The enclosure may inhibit fluid and/or debris from entering at least portions of the enclosure to inhibit fouling and/or other damage to components in the enclosure.

The enclosure may be used inside structures (e.g., buildings, covered stadiums, uncovered stadiums, pavilions, etc.), and/or outside (e.g., in parks, on uncovered patios, etc.). The enclosure may be coupled to elevated portions of a structure, such as walls, overhangs, canopies, and/or other types of ceilings. For example, the enclosure may be coupled to a canopy of an outside structure. The enclosure may be coupled to a wall of a structure. The enclosure may be coupled to a ceiling of a portion of a building, such as an office or a conference room. The enclosure may be coupled to a top portion of a building or a top of a portion of a building (e.g., interior portions, such as an office or conference room, and/or other portions, such as pavilions, etc.). In some implementations, the enclosure may be coupled to a ceiling of a stadium. The enclosure may be directly coupled to the ceiling of a structure (e.g., coupled to a portion of a ceiling or a frame of a suspended ceiling) or indirectly coupled to the ceiling of a structure, in some implementations.

The size and/or shape of the enclosure may be selected based on the location in which the enclosure may be mounted and/or to allow a user access to the area above the ceiling (e.g., to allow a user to at least partially enter an area above a ceiling to, for example, pull cables to couple with components in the enclosure). In some implementations, the enclosure may have a size (e.g., at least approximately 11 inches×at least approximately 11 inches) to allow a user (e.g., a technician, a repair person, etc.) to at least partially fit (e.g., reach arms and/or head at least partially through the enclosure) in the enclosure to access components in the enclosure, to pull cables to the enclosure, etc. In some implementations, the size may be at least partially based on industry standards (e.g., minimum sizes to allow access), government regulations (e.g., building codes related to access hatches), and/or location specific guidelines (e.g., ceiling tile dimensions). A height dimension may be selected to create a specific aesthetic, such as low profile, seamless with other portions of ceiling, etc. In some implementations, the size and/or shape of enclosures may be selected to create a modular kit to allow flexible deployment of the systems.

In some implementations, the size and/or shape of an enclosure may be selected to allow the enclosure to be received in, coupled to, and/or disposed at least partially in an existing opening in a location. For example, in some locations, an access hatch may exist in a ceiling and the enclosure may be sized and/or shaped to be at least partially disposed in the opening to allow replacement of existing communication equipment and/or replacement of the existing housing. In some implementations, the ceiling may include a frame and ceiling tiles. One or more of the dimensions of enclosure may be selected such that the enclosure is approximately the same size as an existing ceiling tile (e.g., such that the enclosure may replace a ceiling tile). Thus, a new opening may not need to be created to allow upgrades (e.g., installation of communication equipment and/or upgrade of communication equipment in an enclosure), which may reduce costs, facilitate installation, and/or allow reuse of one or more of the existing pieces of equipment.

The enclosure may be installed in an opening in a ceiling (e.g., a cut opening and/or an opening created by removing a ceiling tile), in some implementations. The size and/or shape of the enclosure may be selected such that a separate access hatch (e.g., door, panel, etc.) may not be utilized. For example, access hatches may be commonly used with conventional communication housings to allow access to and positioning of cables to be coupled to the conventional communication housings to allow repair, replacement, maintenance, and/or to couple new communication housings. Since the enclosure may be sized to allow appropriate user access (e.g., similar access to access allowed via an access hatch), a separate access hatch may not be used with the enclosures. In some implementations, access to the enclosure may be obtained by removing a shell of the enclosure and/or by removing a back member of the enclosure (e.g., for access to cables proximate to and/or coupled to the enclosure). Not utilizing a separate access hatch with one or more enclosures may increase aesthetics of installations (e.g., less discontinuity with other portions of the ceiling) and/or reduce costs (e.g., when compared with installation and/or maintenance costs associated with installations that include access hatches). For example, access hatches may create an additional discontinuity with a ceiling appearance and may decrease aesthetics. In some implementations, use of access hatches may increase costs since an opening for an access hatch is cut and finished (e.g., since otherwise a rough cut would be visible when installing an access hatch). In some implementations, use of an access hatch may increase installation costs since an access hatch is installed by one or more specialty trade professionals. In some implementations, installation cost and installation time may be increased since additional trade professionals may be needed to complete installation of access hatches (e.g., when compared with installation of the enclosure without a corresponding separate access hatch). For example, to install an access hatch, a painter may be dispatched to finish out a hole cut for the access panel and/or separately to paint the access panel. Even small reductions in costs due increased finish out, time delays, and/or creation of two holes (e.g., access hatch plus enclosure) versus one hole (e.g., enclosure) may result in substantial costs and/or time savings across a project with a plurality of enclosures.

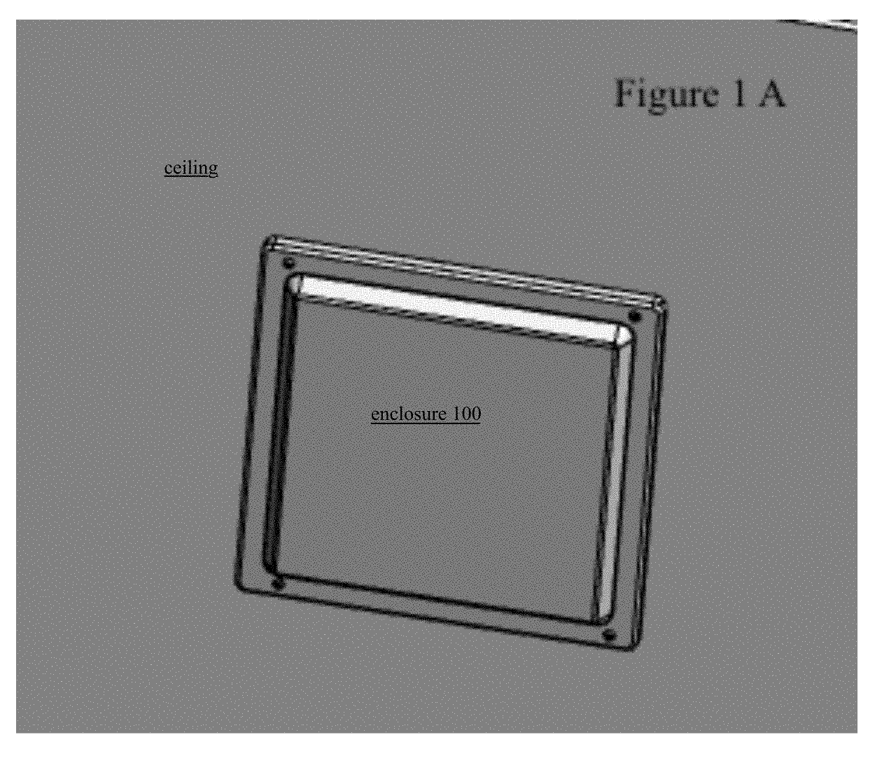

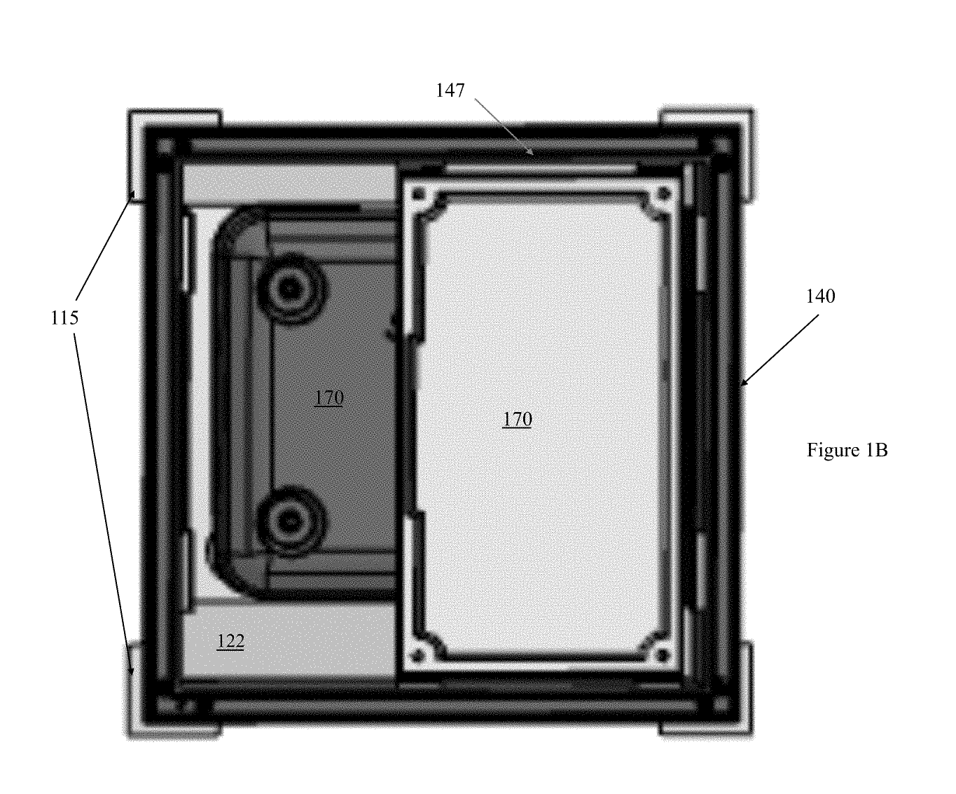

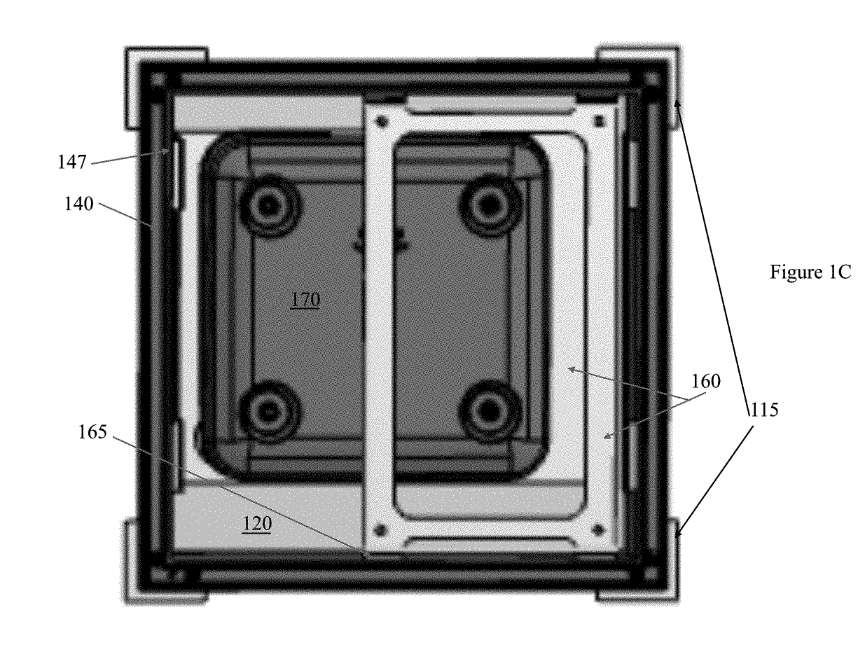

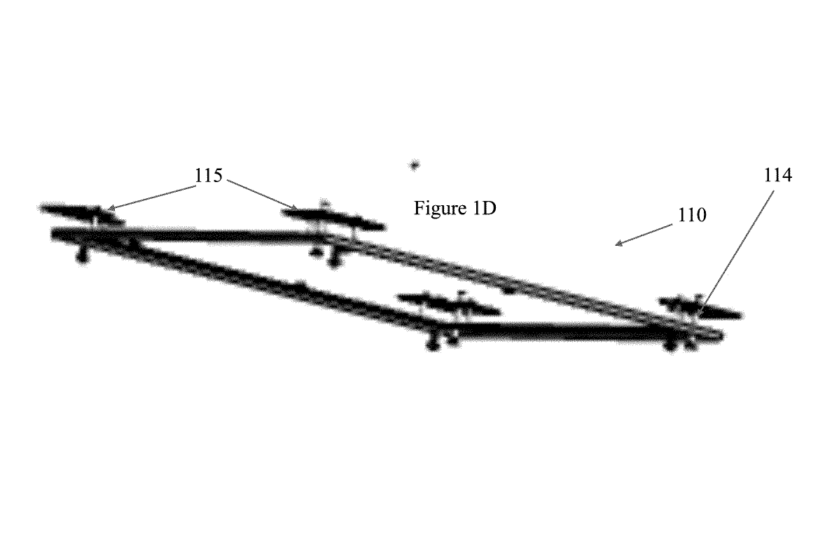

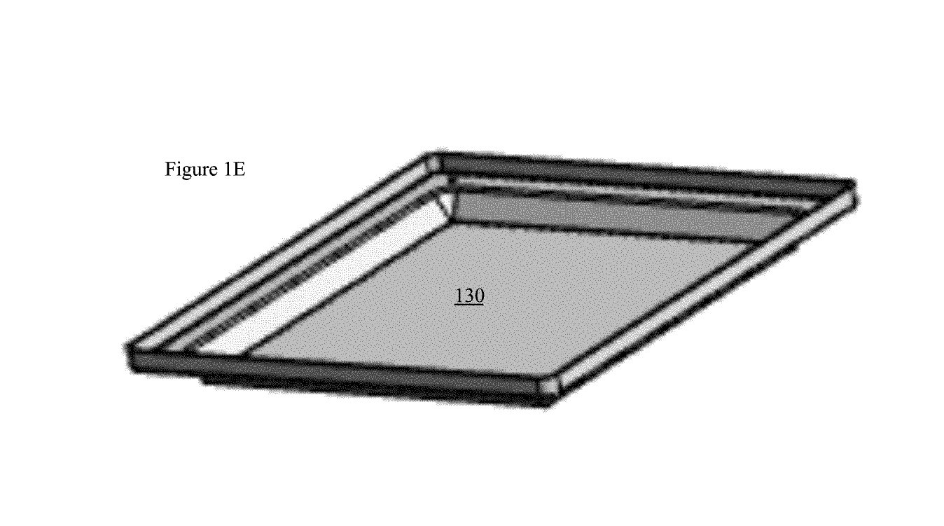

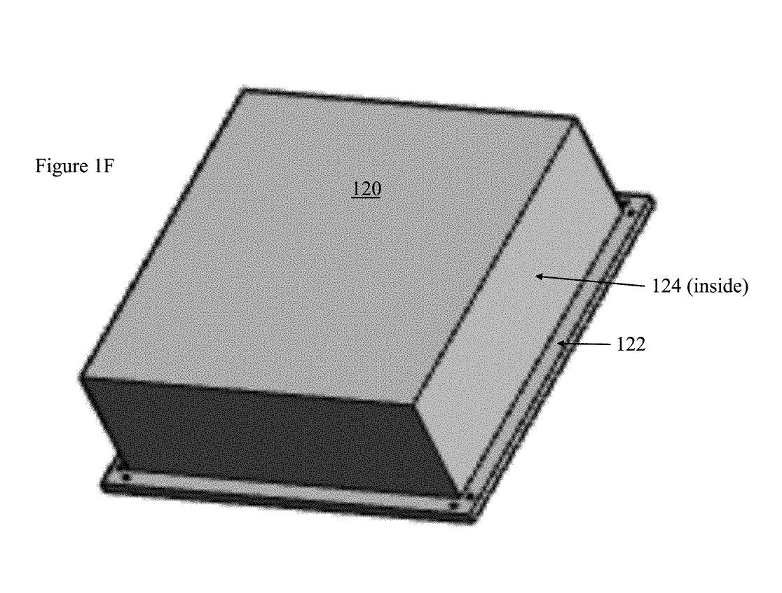

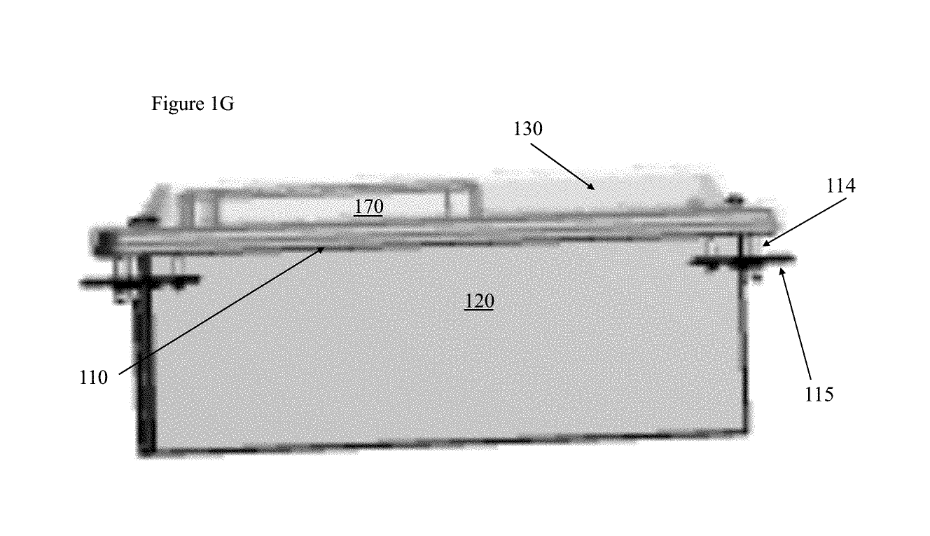

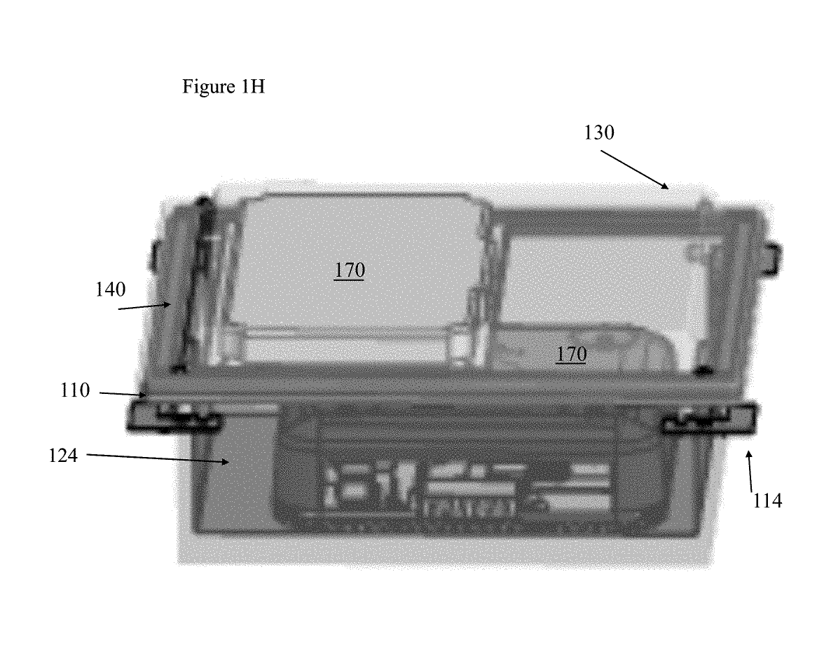

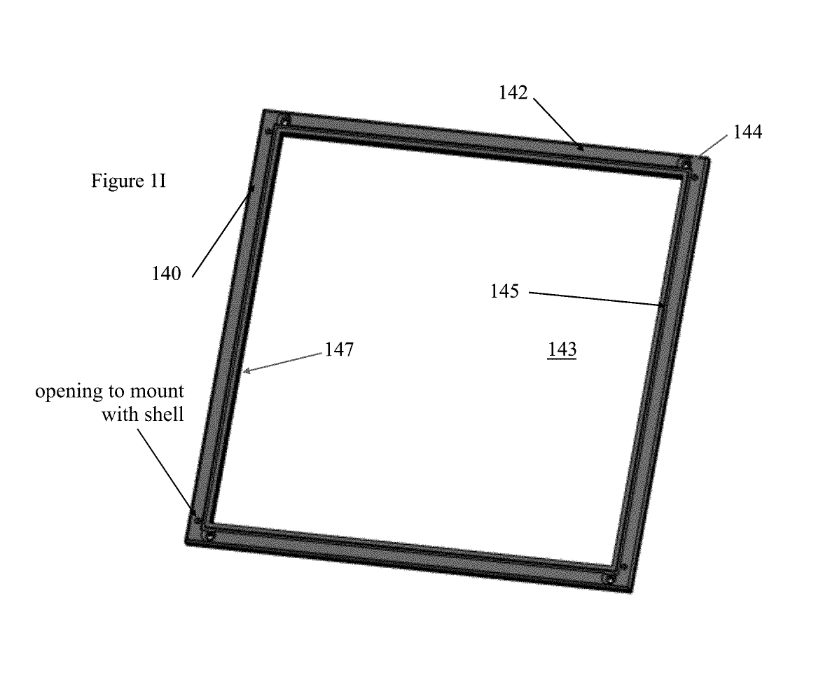

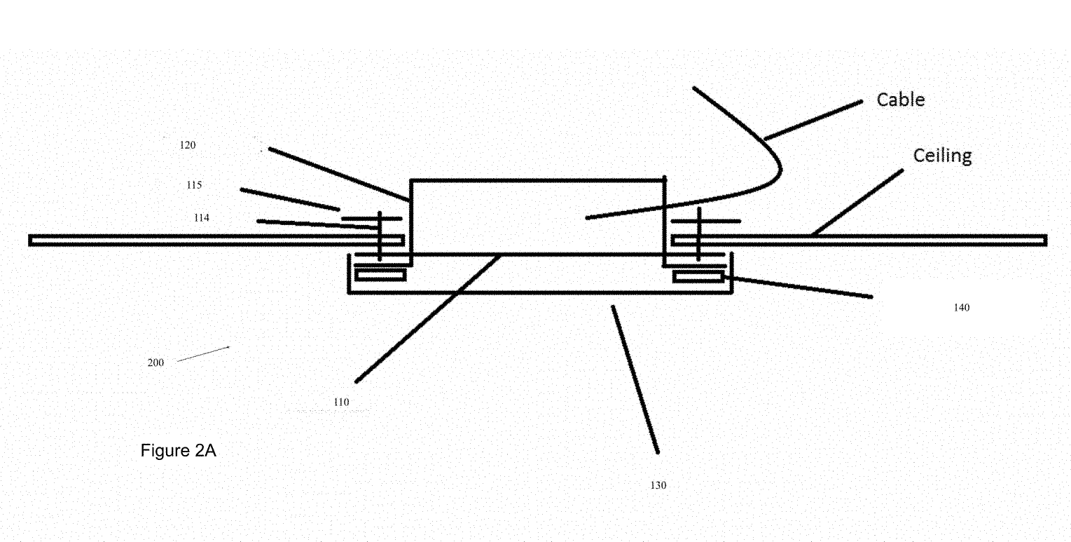

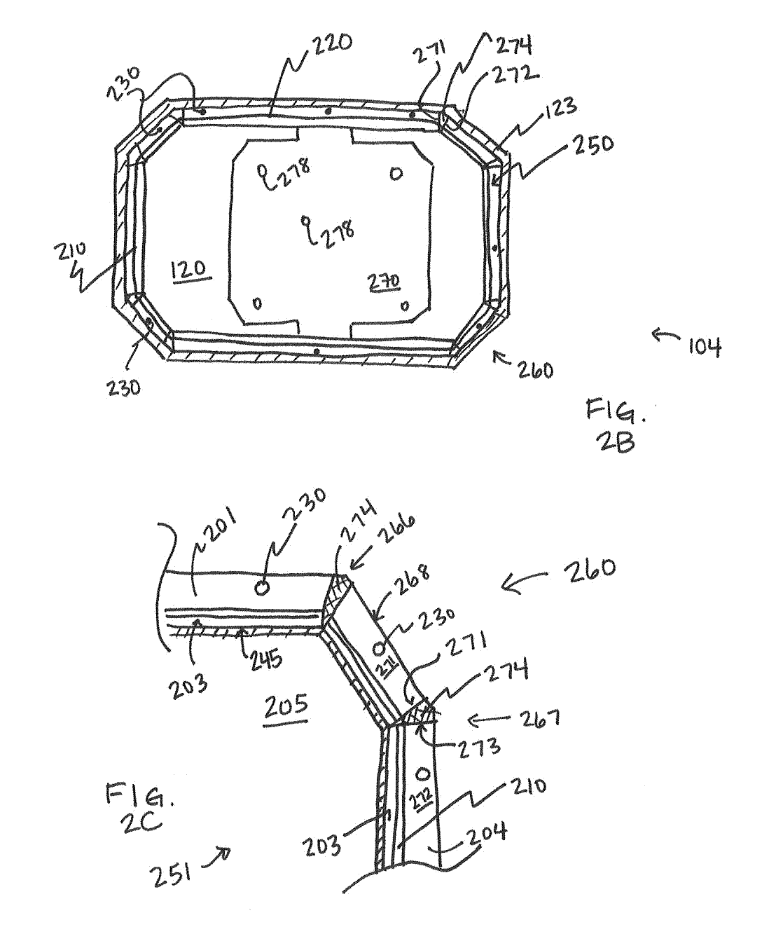

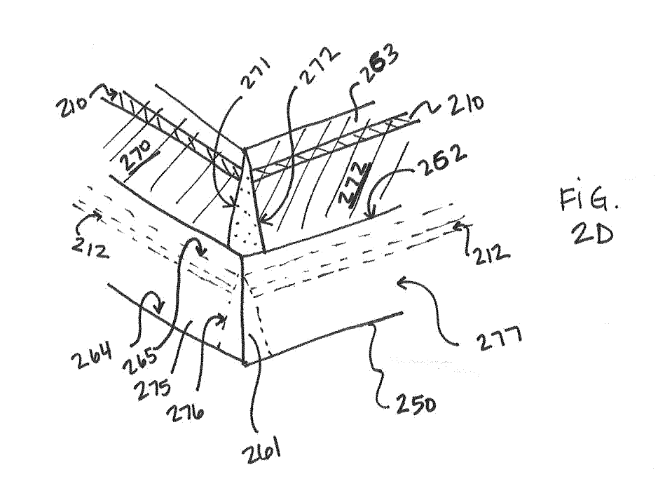

In various implementations, the enclosure may include a finishing bracket, a back member, and a shell. Communications component(s) may be disposed in a cavity of the enclosure. A mounting bracket may be utilized to couple and/or retain component(s) to the enclosure. In some implementations, an enclosure may be installed in a location such as a ceiling. The finishing bracket may be coupled to a ceiling and a back member may be coupled to the finishing bracket. A mounting bracket may be coupled to the back member, and components may be coupled to the mounting bracket (e.g., indirectly via a component bracket or directly) and/or back member. A shell may be coupled to the mounting bracket to create an at least partially enclosed cavity in which the component(s) are disposed. The shell and/or back member may be sealed to the mounting bracket via gaskets (e.g., to inhibit entry of fluids and/or debris). The components may be accessed after installation by removing the shell. Cables (e.g., passing through the back end to be coupled to components) may be accessed for connection to components in other enclosures, maintenance, repair, etc. by removing the enclosure or portions thereof. The opening in which the enclosure is positioned may be large enough (e.g., once the enclosure is removed) to allow a user or a portion of the user to at least partially enter the area above the ceiling (e.g., hands, arms, and/or a head of a user may enter the area above the ceiling), which may facilitate repairs, maintenance, addition, and/or replacement of cables. FIG. 1A illustrates of an implementation of an example enclosure 100. FIGS. 1B-1I illustrate implementations of portions of the example enclosure 100, illustrated in FIG. 1A. FIG. 2A illustrates a cutaway view of an enclosure 200.

As illustrated, the enclosure may include a finishing bracket 110. The finishing bracket 110 may be any appropriate shape, such as rectangular and/or similar to an annular ring. For example, the finishing bracket 110 may have an approximately rectangular ring shape. The finishing bracket 110 may have one or more rounded corners (e.g., to inhibit damage to users, the enclosure, and/or enclosure components from sharp corners). The finishing bracket may include a first side that contacts the ceiling (e.g., gypsum board of the ceiling, frame of the ceiling, etc.) when installed and an opposing second side. In some implementations, the sides of the finishing bracket may be substantially similar to allow orientation of the finishing bracket with either the first side or opposing second side contacting the ceiling. In some implementations, the finishing bracket may include at least one axis of symmetry in a plane parallel to the width and length of the finishing bracket (e.g., to ease installation).

The finishing bracket may include first openings 112 to receive first fasteners 114. The first openings may be disposed proximate each corner of the finishing bracket, disposed across a perimeter of the finishing bracket, on opposing sides of the finishing bracket, and/or any other appropriate configuration. The first fasteners 114 may be utilized to couple the enclosure to a ceiling, for example. A first fastener may be configured to be installed, removed, and/or reinstalled, in some implementations.

The first fasteners 114 may include an anchor 115 (e.g., a clip, flange, expansion anchor, toggles, sleeve, epoxy, etc.), in some implementations. For example, when fasteners are installed in gypsum ceilings, an anchor 115 (e.g., clip) may disperse the load from the enclosure to inhibit damage to the ceiling and/or secure the enclosure to the ceiling (e.g., screws may fall out of gypsum boards over time without anchors and/or may not allow removal and reinstallation in gypsum boards). The anchor may allow the fasteners to couple with a frame of a ceiling system (e.g., portion of a frame that retains ceiling tiles). For example, the anchor may clip onto a lateral member of a frame of a ceiling. The anchor may be coupled to the first fastener (e.g., the anchor may include a threaded opening through which the first fastener is at least partially disposed, the fastener may be bonded proximate to an end of the first fastener, etc.). The anchor may be removable or affixed to the fastener.

During installation one or more first ceiling openings may be created. The first ceiling opening may be an orifice cut in the ceiling. In some implementations, the first ceiling opening may be an approximately 3 inches diameter to approximately 6 inches diameter opening. The first ceiling opening may have dimensions to retain an anchor (e.g., inhibit an anchor from passing through the first ceiling opening when installed). For example, the first ceiling opening may have a length and/or width less than the length and/or width of the anchor (e.g., when expanded, when disposed in position, etc.). At least a portion of the first fastener 114 and the anchor 115 may pass through the first opening 112 of the finishing bracket to be positioned at least partially in the first ceiling opening, the area above the ceiling, and/or in the ceiling to couple the finishing bracket to the ceiling. The anchor may then be retained in this position (e.g., by clipping onto a frame of a ceiling, by expanding, by unfolding, by orienting in a position inhibited from passing through the first ceiling opening, etc.). One or more additional first fasteners 114 and/or additional first anchors 115 may be disposed through additional first openings 112 of the finishing bracket and at least partially through additional first ceiling openings in the ceiling to further couple the finishing bracket to the ceiling. For example, at least two first fasteners and at least two anchors may be utilized to couple the finishing bracket to the ceiling. Since the finishing bracket includes first openings 112, the finishing bracket may be used to at least partially guide the relative positions of the first ceiling openings (e.g., to each other). For example, one first ceiling opening may be created, one of the first fasteners 114 may disposed to couple the finishing bracket to the ceiling, and one or more additional first ceiling openings may be created using the first openings in the finishing bracket as a guide. In some implementations, the finishing bracket may be held in a desired location (e.g., by hand, by adhesive, etc.) and one or more of the first ceiling openings in the ceiling may be created (e.g., by cutting and/or drilling into at least a portion of the ceiling). In some implementations, first openings may be created prior to coupling the first fastener to the ceiling and/or during coupling of the first fastener to the ceiling (e.g., anchors, such as sleeves or toggles may be able to pass through an opening created during insertion of the first fastener).

The finishing bracket 110 may include a second opening 113. The second opening 113 is larger than at least one of the first openings of the finishing bracket. The second opening may have a size and/or a shape that allows a user access to an area above the ceiling (e.g., to allow a user to put his/her hand(s), arm(s), and/or head through the second opening). The second opening may allow access to cables (e.g., communication cables, power supply, etc.) in the ceiling and/or may allow new cables to be run proximate the second opening. For example, a user may access cables in the ceiling (e.g., above the gypsum board ceiling and/or ceiling tiles) to couple with components to be disposed in an enclosure installed at a location to provide communication capability (e.g., CAT4 cable, fiber optic cable, power supply cables, etc.).

The second opening of the finishing bracket 110 may have a size and/or a shape that allows the back member 120 of the enclosure to be disposed at least partially through the second opening. The second opening 113 of the finishing bracket may have a size and/or a shape that allows component(s) (e.g., based on application) to be disposed at least partially in the second opening.

The second opening 113 of the finishing bracket may be a template for a second opening created in the ceiling. For example, once the finishing bracket is coupled to the ceiling via one or more of the first fasteners and one or more first ceiling openings, a second ceiling opening may be created (e.g., cut) in the ceiling using the second opening 113 in the finishing bracket as a guide (e.g., a saw may be allowed to operate proximate the edges of the second opening of the finishing bracket to create a hole similar in size to the second opening of the finishing bracket). In some implementations, the finishing bracket may be held in a desired location (e.g., by hand, by adhesive, etc.) and the second ceiling opening in the ceiling may be created (e.g., by cutting at least a portion of the ceiling using a saw, cutter, etc.). The hole(s) created in the ceiling (e.g., the second opening in the ceiling) may be a rough cut and/or may be unfinished (e.g., not sanded, taped, and/or painted) since the hole may not be visible to others once the enclosure is installed. For example, the second opening in the ceiling may be at least partially covered by the finishing bracket, the back member, mounting bracket, and/or the shell. Installation costs may be reduced by utilizing a second opening that is not visible since costs associated with “finishing” (e.g., painting, sanding, cleanly cutting, etc.) the opening may not be incurred, in some implementations, and/or since it may be less expensive to cut the rough opening (e.g., specialized contractor may not be utilized).

The back member 120 of the enclosure may be disposed at least partially in the second opening of the finishing bracket. For example, the back member 120 may include a flange 122 and at least one cavity 124 disposed between walls of the back member. The flange 122 may extend from wall(s) of the back member and at least partially circumscribe a perimeter of the back member, as illustrated. The flange may include one or more flanges extending from wall(s) of the back member and/or a continuous flange extending from wall(s) of the back member. The flange may or may not have a shape similar to the shape of the back member and/or the mounting bracket. The cavity 124 may be configured to inhibit entry of fluids and/or debris. For example, cavity may include walls and an end, the cavity may allow openings to be sealed (e.g., proximate cable entry/exit points, by a shell, etc.), and/or the cavity may include water resistant materials (e.g., plastic, metal, coatings, etc.). The back member may include one or more orifices to allow cables to pass through a wall of the back member into the cavity of the back member. The cable(s) may then be coupled to one or more components disposed in the enclosure. The orifice may include a sealing member (e.g., o-ring, flexible gasket, etc.) or a sealing fluid may be applied (e.g., epoxy, silicone based, rubber based, etc.) to inhibit fluids and/or debris from entering the cavity of the back member (e.g., since exposure to fluids and/or debris may inhibit performance, increase wear, and/or otherwise damage components disposed in the enclosure), in some implementations. In some implementations, a sealing member and/or sealing fluid may not be utilized.

During installation, the back member 120 of the enclosure may be disposed at least partially in the second opening 113 of the finishing bracket 110 such that the cavity of the back member is disposed proximate a first side 118 of the finishing bracket and the flange of the back member is disposed proximate the opposing second side 119 of the finishing bracket.

The back member 120 may be coupled to the finishing bracket 110. In some implementations, second fasteners may be utilized to couple the back member and the finishing bracket. For example, the flange of the back member 120 may include first flange opening(s) adapted to receive second fastener(s) and/or the finishing bracket 110 may include third opening(s) adapted to receive the second fastener(s). At least a portion of the second fastener(s) may pass through first flange opening(s) and third opening(s) to couple the back member and the finishing bracket. In some implementations, the back member may clip onto the finishing bracket. For example, at least a portion of the flange of the back member may be positioned in a recess of the mounting member to couple the back member and the finishing bracket. In some implementations, the back member (e.g., the flange) may include a recess adapted to receive at least a portion of the finishing bracket (e.g., an edge and/or protrusion of the finishing bracket). The back member may couple directly to the ceiling (e.g., via fasteners, fasteners with anchors, etc.), in some implementations.

A mounting bracket 140 may be coupled to the back member and/or finishing bracket. For example, a mounting bracket similar to the mounting bracket described in U.S. Provisional Patent Application No. 62/327,960 (entitled “Enclosure of Communication Components,” filed on Apr. 26, 2016), where back member is similar to the second shell to which the mounting bracket is coupled. The mounting bracket may allow components 170 to be secured in the enclosure (e.g., in the cavity of the back member and/or proximate the shell). Components may include communication components. For example, the communication components may include wireless access point(s), wireless range extender(s), fiber optic communication equipment, wired communication component(s), controllers, electronic beacon(s), router(s), connectors (e.g., fiber to copper connectors) and/or any other appropriate component. In some implementations, components, such as wireless components, may be coupled to the mounting bracket.

The mounting bracket 140 may include any appropriate material, such as metal, plastic, fiber reinforced plastic, etc. The mounting bracket may be antimony, in some implementations. The mounting bracket may have any appropriate shape and/or size. The size and/or shape of the mounting bracket may be based on the size and/or shape of: components to which the mounting bracket is designed to coupled, the enclosure or portions thereof, and/or fabrication processes. For example, the mounting bracket may have a shape similar to the finishing bracket of the enclosure and/or a flange of the back member. For example, the mounting bracket may include a perimeter portion 142 that is similar in shape to the flange of the back member. The mounting bracket may have a shape similar to an annular ring and/or a rectangle with a rectangular shaped opening, in some implementations. The mounting bracket may be larger, smaller, and/or similar in size to the flange of the back member. The mounting bracket may be larger, smaller, and/or similar in size to the finishing bracket. In some implementations, the size and/or shape of the mounting bracket may be selected at least partially based on an overall aesthetic of the enclosure (e.g., such that the mounting bracket does not extend beyond the flange of the back member, such that the mounting bracket and finishing bracket are similarly sized, such that the mounting bracket does not extend beyond a shell, etc.).

As illustrated, a component opening 143 may be disposed within the perimeter portion of the mounting bracket. Components housed by the enclosure may be coupled to the mounting bracket via the component opening, disposed in a cavity in the back member via the component opening, and/or disposed at least partially in the component opening, in some implementations.

The mounting bracket 140 includes a first side 141 and a second opposing side 142. The first side may be proximate and/or contact the back member 120 and the second opposing side of the mounting bracket may be proximate the shell 130. The mounting bracket 140 may include one or more mounting openings 142 to couple the mounting bracket to the back member 130 and/or finishing bracket 110. One or more fasteners may be at least partially disposed in mounting opening(s) and/or opening(s) in the back member and/or finishing bracket to couple these component(s).

The mounting bracket 140 may include at least one first recess 145 disposed at least partially between the mounting opening(s) 143 and the component opening(s) 144. For example, at least one recess may be disposed on the second side of the mounting bracket between the mounting opening(s) and the component opening(s), in some implementations.

A gasket 150 may allow a seal to be formed when the shell 130 is coupled to the mounting bracket 140. A gasket (e.g., o-ring) may be positionable in the first recess 145 such that at least a portion of the gasket is disposed in the recess and at least a portion of the gasket extends beyond the recess, in some implementations. When a shell is coupled to the mounting bracket 140, the gasket may be at least partially compressed to create a seal. The seal may inhibit fouling of the components by inhibiting entry of fluids and/or debris into the cavity in which the components are disposed, in some implementations.

Positioning the recess and thus the seal formed by the gasket such that fasteners and openings in which the fasteners are disposed (e.g., mounting openings in the mounting bracket) farther away from the component opening of the mounting bracket than the gasket, may inhibit fluids and/or debris (e.g., dust) from contacting components in the enclosure. For example, when fasteners are disposed inside (e.g., proximate the cavity) the gasket, each fastener may be sealed (e.g., via a sealant such as gaskets and/or epoxy). Each of the sealants may then have an opportunity to fail and thus increase the likelihood of failure of a seal of the enclosure. Since exposure to fluids may reduce performance and/or foul (e.g., cause wear and/or damage) components positioned in the enclosure, inhibiting fluids from entering the enclosure may reduce costs associated with repairing and replacing the components (e.g., due to fluid exposure) and/or may improve user satisfaction (e.g., by reducing performance problems based on fluid exposure). For example, chances for fouling of components of the electrical component (e.g., by fluid and/or debris) may increase when using fasteners that penetrate a sealed area (e.g., cavity in the back member) since the probability of failure of seals around a plurality of individual fasteners is greater than the probability of failure of a single seal (e.g., by the gasket). Thus, utilizing an enclosure with a first recess disposed at least partially between the mounting openings and component opening of the mounting bracket may inhibit fouling of components disposed in the enclosure. By positioning the mounting openings and thus the fasteners outside the gasket(s), leaks may be inhibited since the area inside the seal formed by the gasket(s) may not be penetrated by the fastener(s). For example, sealing washers and/or sealing gaskets may not need to be utilized with the fasteners (e.g., as opposed to when fasteners are disposed inside the area sealed by a gasket such as an o-ring), in some implementations.

In some implementations, the seal between the mounting bracket and the shell and/or the mounting bracket and the back member may be opened and closed to allow access to the components positioned in the enclosure (e.g., for maintenance, repair, replacement, etc.). The seal may allow repeat opening and closing to facilitate maintenance, inspections, and/or replacement of the enclosure or portions thereof in some implementations. In some implementations, the gasket that allows creation of the seal may be replaceable. The gasket may be single use and replaced by a new gasket (e.g., when the seal is broken and replaced), in some implementations.

In some implementations, the mounting bracket may include at least one recess on a first side and at least one recess on an opposing side to allow a seal to be created between the mounting bracket and the back member and the mounting bracket and the shell. By creating a seal between the mounting bracket, back member, and shell, debris and/or fluid may be inhibited from entering the cavity in the back member (e.g., in which components may be disposed). For example, the first side of the mounting bracket may include at least one first recess along the perimeter of the mounting bracket and/or the second side of the mounting bracket may include at least one second recess along the perimeter of the mounting bracket. The first recess and the second recess may be disposed on opposing sides of the perimeter mounting bracket. The size and/or shape of the first recess and/or the second recess may be selected based on the type of gasket (e.g., o-ring) that will be utilized to seal the enclosure. The first recess and the second recess may have the same and/or different sizes and shapes. The gaskets used to seal the enclosure may be similar and/or different. The first recess may receive at least a portion of a first gasket, and the second recess may receive at least a portion of the second gasket. The first gasket and the first recess may be selected such that the first gasket extends beyond the first recess. The second gasket and the second recess may be selected such that the second gasket extends beyond the second recess. In some implementations, selecting a gasket that extends beyond a recess may allow the gasket to be compressed to provide a seal. In some implementations, the second recess of the mounting bracket may couple with the ceiling and/or the back end. For example, a second gasket disposed at least partially in the second recess may compress and couple with a portion of the ceiling that contacts the second gasket, when fasteners couple the mounting bracket to the back end, finishing bracket, and/or ceiling.

In various implementations, the mounting bracket may include inner surfaces and outer surfaces. The inner surfaces may be the surfaces of the mounting bracket that are interior to the first recess of the mounting bracket and the outer surfaces may be the surfaces that are exterior to the first recess of the mounting bracket.

The mounting bracket may include one or more mounting openings. The mounting openings may receive a fastener (e.g., screw, bolt, clip, and/or any other appropriate fastener). The mounting openings may be disposed in one or more outer surfaces of the mounting bracket. The mounting opening(s) in the mounting bracket may be disposed about side(s) of the mounting bracket. As illustrated, the mounting openings may be disposed about the mounting bracket at approximately equal distances from each other. In some implementations, mounting openings in the mounting bracket may be proximate to the corners of the perimeter mounting bracket. The mounting openings may be positioned to align with one or more openings in the back member, shell (e.g., to allow coupling of the first shell and mounting bracket), and/or finishing bracket. Thus, fasteners may be disposed at least partially through the openings in the mounting bracket to couple the mounting bracket and the ceiling, shell(s), back member, and/or other components of the enclosure. In some implementations, the fasteners may exert a force to create a seal (e.g., by at least partially compressing at least one gasket in a recess of the mounting bracket).

The mounting bracket may include one or more walls, in some implementations. A wall may be disposed on inner surface(s) of the mounting bracket. A wall may extend from one side of the mounting bracket to an opposing side of the mounting bracket, in some implementations. The wall may include nuts to facilitate coupling of component(s) to the mounting bracket. The wall may include apertures (e.g., slots), protrusions, recesses, and/or other features to facilitate coupling components to the mounting bracket. For example, the wall may include slots that allow direct coupling with a component (e.g., as opposed to and/or in addition to using component manufacturer hardware for coupling). In some implementations, cables associated with components may pass through the apertures in the wall. For example, a power supply cable may pass through aperture(s) to supply components coupled to the mounting bracket with power.

In some implementations, a component may be coupled (e.g., directly and/or indirectly) to the mounting bracket via an appropriate fastening system. For example, a component may include one or more openings and first fastener(s) may be utilized to couple the component to apertures in the wall of the mounting bracket.

In some implementations, the mounting bracket 140 may include groove(s) 147 to couple component bracket(s) 160 and/or component(s) 170 and the mounting bracket. A groove 147 may be disposed on inner surface(s) of the mounting bracket. The groove may extend along at least a portion of one or more sides of the inner surface of the mounting bracket. As illustrated, the groove may extend along a perimeter of the inner surface of the mounting bracket 140.

In some implementations, the mounting bracket 140 may be coupled to one or more component brackets 160. As illustrated, a component bracket may retain a component 170 in a portion of the cavity 124 of the back member 120. The component bracket 160 may include one or more protrusions 165, which may be received by the groove in the wall of the mounting bracket. The components may be slidably or statically coupled to the mounting bracket. In some implementations, slidably coupling components may facilitate access to one or more second components disposed below a first component. For example, the component bracket to which the first component is coupled may be slid from a first portion of the mounting bracket to a second portion of the mounting bracket (e.g., the first portion and second portion may or may not overlap) to allow access to a second component accessible in the first portion.

In some implementations, a groove 147 may extend along each of two opposing sides of the mounting bracket of the enclosure. A component bracket and/or component may include one or more protrusions (e.g., flanges, rims, tongues, etc.) that are received by the groove(s) to couple the component bracket and/or the component to the mounting bracket (e.g., a tongue and groove fastening). For example, a component bracket may include two opposing protrusions. A protrusion may have a thickness to allow deflection of the protrusion and/or include a material that allows the protrusion to be deflected. To couple the component bracket to the mounting bracket, the component bracket may be deformed (e.g., protrusions may be deflected, squeezed, etc.) to allow the protrusions to be positioned at least partially in the mounting bracket. In some implementations, a first protrusion may be disposed at least partially in a first groove of the mounting bracket and then the component bracket may be deformed to position a second opposing protrusion in a second groove (e.g., same or different) of the mounting bracket. The component may be at least partially elastically deformable to allow the component mounting bracket to return to a first shape after deforming the component bracket to a second shape to allow positioning of the protrusions in the grooves of the mounting bracket.

By allowing the component bracket to be coupled to the mounting bracket via the protrusions of the component bracket and the groove of the mounting bracket, installation costs may be reduced (e.g., when compared with using fasteners to couple the component bracket and the mounting bracket), installation may be more quickly accomplished (e.g., since deflecting protrusions to insert into grooves(s) of a mounting bracket may be quicker than using fasteners to couple the component bracket and mounting bracket), at least portions of the coupling of the enclosure may be toolless, and/or installation may be simplified.

In some implementations, the protrusion(s) of the component bracket and/or component may have a size and shape that allows the protrusion to slide in the groove. For example, if a component bracket includes two protrusions (e.g., tongues) on opposing sides of the component, each of the protrusions may be disposed at least partially in the groove (e.g., on opposing sides of the mounting bracket). The protrusion may be coupled to allow the protrusion to move along at least a portion of the groove. For example, a groove of a mounting bracket may include straight sections or straight and curved sections. A protrusion may be allowed to move along at least a portion of the straight section of the groove. A protrusion may not be flexible enough to move through a curved section of the groove, in some implementations. Thus, the component may be slidably coupled to the mounting bracket (e.g., the component may slide along a length or width of the mounting bracket by allowing the protrusion of the component to slide in the groove.) In some implementations, utilizing the groove and protrusion to couple the mounting bracket and component(s) may decrease costs (e.g., fewer separate fasteners, less time to install and/or less specialized technician to install), facilitate installation and/or repair (e.g., since tools may not be required to couple a tongue and groove coupling), and/or increase life of the enclosure (e.g., less probability of material fatigue due to over tightening and/or coupling and/or uncoupling).

Although FIG. 1I illustrates an implementation of an example mounting bracket, the mounting bracket (e.g., a frame) may include other and/or additional features. For example, the mounting bracket may be unibody and/or include segments coupled together. A mounting bracket kit may include one or more segments and an implementation of a mounting bracket may be created by selecting and coupling two or more of the segments together (e.g., via weld, bonding, couplers, and/or any other appropriate coupling mechanism or member). Thus, a mounting bracket may be customized for particular applications. The mounting bracket may be a unibody piece, in some implementations, and created by any appropriate process (e.g., bending a length of mounting bracket into a desired shape and coupling ends of the mounting bracket together, injection molding the mounting bracket, casting the mounting bracket, and/or combinations thereof). The mounting bracket may have any appropriate shape and/or size. The shape of the mounting bracket may include one or more corners that are sharp, rounded, and/or chamfered. For example, as illustrated in FIG. 2A of U.S. patent Ser. No. 15/498,387, which is incorporated herein to the extent that it does not conflict with the teachings of this application, a mounting bracket 200 may include rounded corners. The rounded corners may cause less damage to the shells, installers, wires, etc. (e.g., since the rounded corners may not poke or scratch when as opposed to sharp corners).

In some implementations, the mounting bracket may include one or more chamfered corners. FIG. 2B illustrates a portion 104 of an implementation of an enclosure that includes an example mounting bracket 250 with chamfered corners 255. FIG. 2C illustrates an implementation of a portion 251 of the example mounting bracket 250 illustrated in FIG. 2B, and FIG. 2D illustrates a top view of an implementation of a portion 242 of a chamfered corner 255 of the mounting bracket 250 illustrated in FIG. 2B. As illustrated in FIG. 2B, the mounting bracket 250 may be disposed in flange 123 of a back member 120. The flange 123 may or may not include retention members (e.g., protrusions, recesses, textures, etc.) to retain the mounting bracket (e.g., 250 and/or other described mounting brackets) in the flange. In some implementations, the mounting bracket may be coupled to the back member. As illustrated, the mounting bracket may be sized and/or shaped, in some implementations, to be self-aligning. The mounting bracket 250 may include one or more recesses 210, 212 (e.g., on the top section and/or bottom section) in which gaskets 220, 222 may be partially disposed, openings to receive fasteners (e.g., for coupling to shell(s)), and/or slot(s) to facilitate coupling with component brackets 270.

As illustrated, the back member of the enclosure may include a body with a cavity 205 disposed in the body. For example, the body of the cavity may have parts that are coupled to at least partially surround a cavity. Component brackets 270 and/or components 280 may reside in the cavity 205, upon assembly with the enclosure and/or during use. The mounting bracket 250 may include one or more pairs of opposing sides, for example the mounting bracket may include a top section 201 and a bottom section 202. The mounting bracket 200 may include an inner surface 203 and an outer surface 204. The inner surface(s) 203 may extend from recess(es) capable of receiving the gasket(s) (e.g., first recess and/or second recess) towards the cavity. The outer surface 204 may extend from the recess(es) capable of receiving the gasket(s) towards the outer wall.

The mounting bracket 250 may include chamfered corners 255. As illustrated, the mounting bracket 250 may include an outer wall 251, top section(s) 201, and a bottom section(s) 202. A top section of the mounting bracket may be continuous and/or include more than one portion. A bottom section of the mounting bracket may be continuous and/or include more than one portion. In some implementations, a first end 262 of the top section 201 may be coupled to the outer wall 251 and a second free end 263 of the top section 201 may extend away from the outer wall; and, a first end 264 of the bottom section may be coupled to the outer wall and a second free end 165 of the bottom section may extend away from the outer wall. For example, the mounting bracket may be may be a piece of metal that is bend twice to create an outer wall (e.g., with a planar surface, rounded surface, and/or any other appropriately shaped surface) with the top section 201 and the bottom section 202 extending away from the outer wall, as illustrated in FIG. 2D. In some implementations, the top section and/or bottom section may be coupled (e.g., welded, bonded, etc.) to the outer wall.

A chamfered corner of the mounting bracket may include one or more corners. As illustrated in FIG. 2C, a chamfered corner 260 may include a first corner 266, a second corner 267, and an angled section 268 disposed between the first and the second corners. In some implementations, a corner (e.g., first corner and/or second corner) of the chamfered corner of the mounting bracket may be created by creating a cutaway portion in a top section of the mounting bracket (e.g., by cutting, burning, notching, and/or otherwise forming an opening; and/or by forming the top section with the openings) to create a first top section 270 and a second top section 272. The first top section 270 and the second top section 272 may be disposed proximate each other (e.g., the first edge 271 of the first top edge may be proximate the second edge 273 of the second top section 272) and at least partially separated by a gap 274 prior to forming the corner. The first top section and the second top section may then be bent towards the bottom section (e.g., downwards). For example, the free ends 263 of the first 270 and second 272 top sections may be bent such that the free ends of the first and second top sections are disposed more proximate each other (e.g., when compared with when the top sections are aligned perpendicularly with the outer wall). In some implementations, the bent top section (e.g., the first top section and the second top section) may form a plane approximately perpendicular and/or slanted (e.g., as opposed to parallel with the outer wall) relative to the outer wall. In some implementation, the gap 274 between the free ends of the first and second top sections may be less than and/or approximately equal to the gap between the opposing ends of the first and second top sections (e.g., proximate outer wall). The free ends of the first and second top sections may or may not contact (e.g., the free ends may touch and/or overlap). In some implementations, the free ends of the first and second top sections may not overlap to reduce overall size of the mounting bracket. Since the enclosures are generally considered obstructions, any reduction in size increases user satisfaction and/or safety (e.g., by reducing the likelihood of inadvertent bumping into the enclosure).

In some implementations, use of a chamfered corner may decrease costs. Since the mounting bracket may have a large size (e.g., when enclosing large components or a large number of components), the billet utilized to produce a chamfered cornered mounting bracket may be smaller than a billet utilized to produce a similarly dimensioned rounded and/or sharp corner mounting bracket. In some implementations, manufacture may be facilitated and/or manufacturing costs may be decreased by using a folded mounting bracket when compared to square mounting bracket and/or a mounting bracket with straight segments and angled corners. For example, since the angles may need to be calibrated angles to achieve a specified shape when fitting segments and corners together manufacturing may be more difficult and/or costs for producing segmented mounting brackets may be higher (e.g., when compared with chamfered corners). However, when chamfered corners or otherwise folded frame corners (e.g., square folded corners) are utilized, manufacturing may be facilitated and manufacturing costs may decreased (e.g., since straight piece may be folded to create the folded frame corners). In some implementations, overall product lines costs may be decreased since fewer customized pieces may need to be manufactured and/or stored (e.g., since folded frame mounting brackets may be created as needed and in sizes customized for projects).

In some implementations, the folded corner (e.g., as described in the chamfered corner) may be utilized to create a plurality of shapes, such as rectangles, squares, shapes similar to an oval, and other regular and/or irregular shapes. The mounting brackets may be custom created for particular applications (e.g., deployment of enclosures in stadiums) and/or created on demand in standard sizes length(s) of straight mounting bracket (e.g., top sections and bottom sections joined by an outer wall, with recess(es), etc.), in some implementations.

In some implementations, the chamfered corner may include gaps 274 between the first and second top sections. The chamfered corner may include gaps between the segments of first recess disposed in the top section (e.g., first and second top section). The gasket may continue over the gap, in some implementations. In some implementations, the size of this corner gap (e.g., proximate the free ends of the first and section top sections and/or the opposing ends of the first and second top sections) may be minimized to inhibit leaking and/or creation of a seal (e.g., to reduces openings through which leaks may enter). For example, the size and/or shape of the cutaway portion made in the top section may be selected to minimize the gap. For example, the cutaway portion may have a first end proximate the outer wall that is smaller than the second opposing end of the cutaway portion that is proximate the free ends of the top section (e.g., triangular).

In some implementations, a bottom section may include one or more chamfered corners that are similar to the top section chamfered corners. For example, the bottom section may include a first bottom section 275 and a second bottom section 277 created by a cutaway portion. The free ends of the first bottom section and the second bottom section may be bent to create the chamfered corner. For example, the first bottom section 275 and the second bottom section 277 may be disposed proximate each other (e.g., the first edge 276 of the first bottom edge may be proximate the second edge 278 of the second bottom section 277) and at least partially separated by a gap 279 prior to forming the corner. The bottom section may include a recess 212 (e.g., single recess and/or with segments) in which a second gasket 222 may be disposed.

Although the corner of the chamfered corner has been described, similar processes may be utilized to create other corners of implementations of the mounting bracket (e.g., sharp corners, rounded corners approximated using a plurality of corners closely spaced together).

The chamfered corner may or may not include openings (e.g., to receive fasteners, such as fasteners that couple the mounting bracket to shell(s)). For example, the angled section of the mounting bracket may include an opening to receive a fastener (e.g., to couple the mounting bracket to at least one of the shells). The openings 230 in the mounting bracket (e.g., in the corners and/or not in the corners) may be disposed in the outer surface of the mounting bracket. Disposing the fasteners in the outer surface of the mounting bracket may inhibit leaking. For example, since an opening in the mounting bracket may receive a fastener that extends through at least one of the shells, leaks (e.g., fluids and/or debris) may enter via the opening in the shell through which the fastener is disposed. By positioning this opening in the outer surface of the mounting bracket, leaks may stay outside the seal formed by gasket(s) disposed in the recess(es) of the mounting bracket and may not contact components within the shells. Thus, damage to the components residing in the cavity of the shells may be inhibited.

One or more slots may be disposed in the mounting bracket between the free ends of the top section and the bottom section. The slots may allow the mounting bracket and the components to be coupled. For example, a slot may be capable of receiving a portion (e.g., protrusion) of a component bracket and/or component. In some implementations, the mounting bracket may include a groove (e.g., on the top section(s) and/or bottom section(s)) capable of receiving a portion of the component bracket and/or component.

In some implementations, the chamfered corners may cause less damage to the shells, installers, wires, etc. (e.g., since the rounded corners may not poke or scratch when as opposed to sharp corners). The chamfered corners of the mounting bracket and/or shell may have greater strength than rounded and/or sharp corner mounting brackets and/or shells. The chamfered corners may resist bending and/or denting to a greater degree than rounded and/or sharp corners. In some implementations, the chamfered corners may reduce manufacturing costs (e.g., by allowing less expensive shell formation processes such as thermoforming).

A shell may be coupled to the mounting bracket. The shell may have any appropriate size and/or shape. The shell may or may not have a shape similar to the mounting frame and/or back member. For example, the shell or portion thereof may have a shape similar to the flange of the back member (e.g., the flange may be a rectangular annular ring and the shell may have a rectangular shape). The shell may include a rim that at least partially covers an edge of a finishing bracket, back member, and/or mounting bracket. For example, a shell may have chamfered corners, rounded corners as illustrated in FIG. 1A, and/or sharp corners.

The shell may cover the cavity of the back member and/or at least a portion of the mounting bracket, in some implementations. Coupling the shell to the mounting bracket may create a partially enclosed cavity in the enclosure (e.g., in which the components may be disposed). The shell may couple to the mounting bracket via shell fasteners. For example, each shell fastener may be disposed at least partially in an opening in the shell and at least partially in an opening in the mounting bracket to couple the components together. In some implementations, a fastener may be disposed at least partially in an opening of the shell, the mounting bracket, and one or more other components of the enclosure. The shell may clip or otherwise couple to the mounting bracket, in some implementations. For example, a portion of the shell (e.g., a flange or other protrusion from the shell) may be disposed in a recess of the mounting bracket. The shell may at least partially wrap around the mounting bracket to couple with the bracket (e.g., the shell may be at least partially flexible and allow manipulation of the shell to snap over an edge of the mounting bracket, in some implementations. Coupling the shell to the mounting bracket and/or other components of the enclosure may generate a force to compress one or more gaskets of the mounting bracket, in some implementations.

The shell may include material that is rigid, semi-rigid, and/or flexible. For example, a rigid and/or semi-rigid material may be utilized to provide impact resistance (e.g., when the enclosure is disposed in wall(s) and/or ceiling(s) which might be in contact with users, objects that a user carries, etc.). For example, a shell may be selected that provided impact resistance when the enclosure is mounted on a wall near walkways or other user congregation locations. In some implementations, a shell may be selected that provides impact resistance when the enclosure is mounted on a ceiling of a location in which tall objects are transported or disposed, such as conference rooms and/or exhibit halls.

In some implementations, the shell may be capable of not substantially deforming when a predetermined amount of force is applied (e.g., a person passing by the enclosure may strike or bump the enclosure without substantially deforming the enclosure). For example, when a person bumps a ladder into the enclosure the shell may not be substantially deformed (e.g., the deformation may not cause damage to the components positioned in the enclosure). The shell may be capable of not substantially deforming in typical traffic for a location in which the enclosure will be installed. In some implementations, the shell may be flexible (e.g., to allow coupling to portions of the enclosure, to resist breakage on impact, etc.) when a force is applied to the shell and return to a substantially similar shape and/or size after the force is removed.

The shell may include waterproof and/or water resistant material (e.g., the shell, a layer of the shell, and/or a coating of the shell may be waterproof and/or water resistant). For example, the shell may include a plastic, fiber-reinforced plastic, and/or any other appropriate material. In some implementations, the type of materials included in the shell may be based at least partially on the location of the enclosure during use. For example, when the enclosure is used in an outdoor stadium where temperatures fall below 20 degrees Fahrenheit, a material that does not substantially degrade (e.g., shatter, deform, etc.) below 20 degrees Fahrenheit may be utilized. As another example, when an enclosure is used in an outdoor location subject to acid rain, the first shell may include material (e.g., a coating, layer, and/or the shell) that resists damage from acid rain. For example, the shell may include a plastic such as ABS (acrylonitrile butadiene styrene). An enclosure that includes ABS may be at least partially impact resistant and/or allow use in wide range of temperatures (e.g., approximately −5 degrees Fahrenheit to approximately 125 degrees Fahrenheit).

The shell may be formed using processes such as thermoforming, injection molding, cast molding, press molding, and/or any other appropriate process. In some implementations, the shell may have an approximately uniform thickness. The uniform thickness may reduce distortion of communication signals, in some implementations. The shell may be pre-finished and/or finished on site (e.g., stained, painted, etc.). The shell or portions thereof (e.g., coating) may resist stains, mildew, and/or mold. The shell may inhibit entry by animals such as insects to maintain cleanliness and/or aesthetics (e.g., inhibit appearances such as translucent cover filled with dead bugs).

The enclosure may be utilized in communication systems, in some implementations. Thus, at least a portion of a shell of the enclosure may allow communication signals to be received and/or transmitted to other devices through the portion of the shell. The shell or portions thereof may not cause substantial signal loss (e.g., less than 1 dB signal loss in communications from and/or to wireless components in the enclosure). For example, the shell may include a material that allows signals (e.g., communication signals, such as wireless, IR, Bluetooth, etc.) to substantially pass through the material. For example, the shell(s) (e.g., a unibody shell and/or modular shell) may include an RF neutral plastic. Thus, the shell may provide protection (e.g., from impact and/or fluid exposure) while not causing substantial signal loss.

In various implementations, the enclosure may be installed in a portion of a wall and/or ceiling. An opening may be created in a portion of a surface. For example, a first opening may be cut in a wall or ceiling. A first fastener(s) may be disposed in finishing bracket opening in the finishing bracket, and the first opening in the surface. The first fastener may include an anchor that is retained in the first opening and couples the finishing bracket with the surface. One or more additional first openings may be created in the surface and one or more additional first fasteners may be coupled to the surface via the additional openings. The finishing bracket may be used as a template to guide the creation of the additional openings in the surface. Thus, the finishing bracket may be coupled to the surface (e.g., a ceiling and/or wall) via one or more first fasteners. An orifice may be created (e.g., cut) in the surface. A second opening in the finishing bracket may or may not be used as a template to create the orifice in the surface. The orifice may be larger than the first openings in the surface. The orifice may be smaller and/or approximately the same size as the second opening in the finishing bracket, in some implementations. For example, the finishing bracket may be a member with a second opening through the member, such as an annular ring (e.g., circular, rectangular, square, oblong, regularly shaped, irregularly shaped, etc.). The second opening may have a size that allows at least a portion of a user (e.g., arms and/or head of a user) to pass through the second opening to an inner area (e.g., an area behind the surface). Access to the area behind the surface may facilitate cabling of components (e.g., to provide power and/or connectivity). A back member may be disposed at least partially through the second opening in the finishing bracket and the orifice in the surface. The back member may be coupled to the finishing member, for example via fasteners disposed through aligned openings in the back member and the finishing bracket. The fasteners may extend at least partially through the ceiling and/or wall, in some implementations. Cabling may be pulled through an opening in the body of the back member, in some implementations.

A mounting bracket may be provided that is coupled to the back member. For example, the mounting bracket may be coupled to the back member via fasteners, adhesives, and/or any other appropriate coupling. The mounting bracket may positioned in a recess in the flange of the back member, in some implementations. The mounting bracket may be disposed within the flange of the back member, in some implementations.

Component brackets may be coupled to a mounting bracket that is coupled to the back member. Component brackets may be coupled by inserting protrusion(s) of the component bracket into one or more slots of the mounting bracket to allow toolless coupling of the component with the mounting bracket, in some implementations. The component bracket may be coupled to the mounting bracket via fasteners or any other appropriate coupling member. The component bracket may be slidably and/or fixedly coupled to the mounting bracket. Slidably coupling the component bracket may facilitate access to a component coupled to the component bracket or another component bracket (e.g., a first component bracket may be moved to allow access to another component positioned, for example, below the first component bracket). One or more electrical component may be coupled to each of the component brackets in the enclosure.

The shell of the enclosure may be coupled to the surface (e.g., of the ceiling and/or wall) by coupling the shell to the mounting bracket. Coupling a shell to the mounting bracket may compresses a first gasket disposed in a first recess of the mounting bracket and/or a second gasket disposed in a second recess of the mounting bracket. Compressing the first gasket and/or second gasket may create a seal (e.g., between the shell and the mounting bracket and/or the mounting bracket and the back member).

In various implementations, once the enclosure is installed, the enclosure or portions thereof may be removed and/or replaced. For example, the shell may be removed to access components for repair, maintenance and/or replacement. A first component may be removed and replaced by a second component by snapping out the component bracket that includes the first component and replacing it with a different component bracket that includes the second component, in some implementations. This may allow existing enclosures to be upgraded quickly and cost-effectively. In some implementations, access to cables may be obtained by removing the enclosure (e.g., when access hatches are not utilized). The access may allow the cables to be repaired, maintained, and/or replaced. The access to the cables may allow cables to be pulled to new locations to facilitate deployment of additional enclosures (e.g., as location needs change, as funding allows, etc.).

In some implementations, the enclosure may be provided as a kit and coupled together and installed at a location. For example, the enclosure kit may include a finishing bracket, back member, mounting bracket and shell. The finishing bracket may be directly coupleable to a ceiling and/or a wall. The finishing bracket may include a first side that is installed proximate to the ceiling and/or wall and a second opposing side. The first side may contact a surface of the ceiling and/or wall, in some implementations. The finishing bracket may include finishing bracket openings to allow coupling with a surface (e.g., a ceiling and/or wall) and/or to allow coupling with other components such as the back member (e.g., finishing bracket openings may align with openings in the back member and/or other components to allow coupling component(s) together). The finishing bracket may include an opening disposed through the finishing bracket (e.g., the opening may align with an opening in the surface to allow access by users to an area behind the surface).

The back member of the enclosure may include a body that is capable of being disposed at least partially through the opening of the finishing bracket. The body of the back member may extend through the orifice in the surface and the second opening of the finishing bracket. The body of the back member may include an opening through which cabling may pass from an inner area of a surface (e.g., behind a ceiling and/or wall) into the cavity of the body to allow the cabling to be coupled with component(s) disposed in the enclosure. The back member may include a flange extending from at least a portion of the body proximate an end of the body of the back member. For example, the flange may include several flanges and/or a ring extending from one or more sides of an end of the body of the back member. The flange may include a first side, which is coupleable to the second side of the finishing bracket, and an opposing second side.

The enclosure kit may include a mounting bracket and/or allow selection and/or creation of a mounting bracket. For example, the mounting bracket may include sharp corners, rounded corners, and/or chamfered corners. The mounting bracket may or may not have a similar shape to the flange of the back member. The mounting bracket may include a first side, which is coupleable to a second side of the back member; a second opposing side; and an outer wall disposed between the first side and the second side. The mounting bracket may include one or more recesses, which are capable of receiving at least a portion of a gasket. For example, one or more recesses may be disposed on the first and/or second sides of the mounting bracket. The mounting bracket may include one or more openings through the mounting bracket and disposed between the outer wall and the recess(es). Opening(s) may be capable of receiving a fastener to couple the mounting bracket to other components of the enclosure, such as the back member and/or shell.

The enclosure kit may include gasket(s) positionable at least partially in the recess(es) of the mounting bracket. A gasket may extend beyond the recess to allow compression of the gasket when the mounting bracket is coupled to another component of the enclosure. Compression of a gasket in a recess may create a seal (e.g., to inhibit entry of debris and/or fluids). By positioning openings (e.g., aligning openings) on top and bottom surfaces of the mounting bracket (e.g., relative to the outer wall) between the outer wall and the recess(es), leaks into areas in which components are disposed may be inhibited (e.g., since the openings are not disposed in the area inside the seal created by the gasket(s)). For example, components may be coupled to the mounting bracket such that the components reside in the cavity of the mounting bracket and the cavity of the back member. The gaskets may surround the cavity of the mounting bracket, and the openings to couple the mounting brackets may be disposed exteriorly to the gasket (e.g., on an opposing side of the gasket as the cavity). Thus, leaks may be inhibited and/or the enclosure may be water resistant.

The mounting bracket may be capable of coupling with one or more electronic components (e.g., directly and/or indirectly via component brackets). Components (e.g., electrical components) may be pre-coupled to component brackets (e.g., to facilitate installation) and/or not pre-coupled (e.g., to allow on-site customization).

The enclosure kit may include a shell that is coupleable to the second side of the mounting bracket such that the one or more components coupled to the mounting bracket are at least partially enclosed between the shell and the back member. Coupling the shell to the mounting brackets may generate a force that at least partially compresses the second gasket in the recess of the mounting bracket to form a seal between the shell and the mounting frame.

Fasteners may be utilized to couple a component of the enclosure to other enclosures and/or the surface (e.g., of the wall and/or ceiling). The fasteners coupling the finishing bracket to the surface may include anchors to retain the enclosure to the surface (e.g., to support the weight of the enclosure and/or coupled components without damaging the surface). Fasteners may exert a force on the gasket(s) in recess(es) of the mounting bracket to create seals to inhibit leaks.

The described processes may be implemented by various systems, such as the described systems. In addition, various operations may be added, deleted, and/or modified. In some implementations, a described process or portions thereof may be performed in combination with other processes. For example, in some implementations, one or more portions of the enclosure may be coupled prior to disposing the enclosure in a location. The components may be coupled to a mounting bracket prior to coupling the mounting bracket to other portions of the enclosure (e.g., back member). The back end and the mounting bracket may be coupled prior to installation of the back end in the opening in a location (e.g., second ceiling opening or wall opening). The back end and the mounting bracket may be a unibody member in some implementations.

In some implementations, the finishing bracket may be installed, then the back member may be disposed in the second opening of a location and coupled to the finishing bracket. The mounting bracket may be coupled to the back member and component(s) may be disposed in the cavity of the enclosure (e.g., coupled and/or uncoupled to the mounting bracket). The shell may then be coupled to the portions of the enclosure coupled to the location.

In various implementations, seals have been described. The seal may inhibit fluid and/or particulate from entering the seal via the sealed area. The seal may be reusable and/or replaceable, in some implementations.

In some implementations, one or more of the components of the enclosure may include a surface with an adhesive (e.g., tacky surface, glue, peel off paper backing to reveal adhesive, etc.). The adhesive portion may at least partially retain the component while fasteners are disposed in the component (e.g., to couple the component to the ceiling and/or other components). For example, the finishing bracket may include an adhesive on at least a portion of a side of the finishing bracket that contacts the ceiling.

The adhesive may retain or partially retain the finishing bracket while openings are cut and/or fasteners are disposed in the finishing bracket. In some implementations, the mounting bracket may include an adhesive on a portion of the perimeter portion that contacts the back member and/or finishing bracket. The adhesive portion of the mounting bracket may couple with or partially retain the mounting bracket in contact with the back member to facilitate installation (e.g., so a user could use the adhesive portion to temporarily affix the mounting bracket driving fasteners into the mounting bracket; to allow two handed fastener installation, and/or to replace the use of fastener(s), etc.).

In some implementations, installation may utilize standard tools rather than specialty keys and tool sizes to facilitate installation.

In some implementations, the shell of the enclosure may be selected to minimize negative impacts to the aesthetics of a location (e.g., as opposed to metal grates, large obtrusive projections extending from a ceiling, locks on ceilings etc.). For example, the shell may be paintable, wallpaperable, etc. The shell may have a color and/or texture to approximate a surface of installation, in some implementations. For example, a shell may have a color that is similar to common ceiling colors in commercial settings. In some implementations, locks and/or other security features may be located below a shell (e.g., to reduce negative impact to aesthetics with the appearance of a lock.) For example, a lock may secure a component to a mounting bracket and/or a security component (e.g., grate, panel, etc.) may be disposed over at least a portion of the component opening of the mounting bracket to inhibit theft and/or intentional damage). The shell may at least partially cover the lock and/or security component.

Although the enclosures have been discussed in various implementations as used in existing buildings and/or structures, the enclosures may be utilized in new construction as well. Use of the enclosures may allow flexibility and/or ease of maintenance since cables may be accessed via the enclosure.

Although the enclosures have been discussed in various implementations as installed in ceilings, the enclosures may be disposed on other surfaces such as elevated surfaces (e.g., canopies, walls, etc.) and/or other surfaces. For example, an enclosure may be installed in a wall of a location. First wall opening(s) (e.g., similar to a ceiling opening) may be created (e.g., an orifice may be cut in a wall) to allow coupling of the finishing bracket to the wall. First fastener(s) with corresponding anchor(s) may pass through first opening(s) of the finishing bracket and through the first wall opening(s) to at least partially couple the finishing bracket to the wall. A second opening in the wall may be created and to allow access to cable(s) in a wall and/or installation of new cables in a wall. The enclosure may then be assembled (e.g., back member, mounting bracket, and/or shell(s) may be coupled to the finishing bracket and/or the wall).

U.S. Provisional Patent Application No. 62/327,960 (entitled “Enclosure of Communication Components,” filed on Apr. 26, 2016) is hereby incorporated by reference to the extent that it does not conflict with the teachings of this disclosure

Although users have been described as a human, a user may be a person or a group of people.

It is to be understood the implementations are not limited to particular systems or processes described which may, of course, vary. It is also to be understood that the terminology used herein is for the purpose of describing particular implementations only, and is not intended to be limiting. As used in this specification, the singular forms “a”, “an” and “the” include plural referents unless the content clearly indicates otherwise. Thus, for example, reference to “a component” includes a combination of two or more components and reference to “a gasket” includes different types and/or combinations of gaskets.

Although the present disclosure has been described in detail, it should be understood that various changes, substitutions and alterations may be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. An enclosure comprising:
a finishing bracket, wherein the finishing bracket is directly coupleable to at least one of a ceiling or a wall, wherein the finishing bracket comprises:
a first side proximate at least one of the ceiling or the wall upon installation;
a second opposing side; and
an opening disposed through the finishing bracket;
a back member, wherein the back member comprises:
a body, wherein at least a portion of the body is disposed at least partially through the opening of the finishing bracket;
a flange extending from at least a portion of the body proximate an end of the body of the back member; wherein the flange comprises:
a first side, and wherein the first side of the flange of the back member is coupled to the second side of the finishing bracket; and
an opposing second side;
a mounting bracket, wherein the mounting bracket comprises:
a first side, wherein the first side is coupled to a second side of the back member;
a second opposing side;
an outer wall disposed between the first side and the second side;
a first recess disposed in the first side;
a first gasket disposed at least partially in the first recess, wherein coupling the first side of the mounting bracket to the second side of the back member compresses the first gasket to create a first seal between the mounting bracket and the back member;
a second recess disposed in the second side; p2 a second gasket disposed at least partially in the second recess;
one or more inner surfaces disposed between the first recess and an edge of the first side and between the second recess and an edge of the second side;
one or more opposing outer surfaces disposed between the first recess and the outer wall and between the second recess and the outer wall;
one or more openings disposed in at least one of the outer surfaces and through the mounting bracket, and wherein each opening is capable of receiving a fastener to couple the mounting bracket to the back member;
wherein the mounting bracket is capable of coupling with one or more electronic components; and
a shell coupled to the second side of the mounting bracket such that components are at least partially enclosed between the shell and the back member and such that the second gasket is at least partially compressed to form a seal between the shell and the mounting frame.

2. The enclosure of claim 1 wherein the second side of the back member comprises a back recess capable of receiving the mounting bracket.

3. The enclosure of claim 1 wherein the finishing bracket comprises one or more finishing bracket openings, further comprising one or more first fasteners disposed at least partially through one or more of the finishing bracket openings to couple the finishing bracket to at least one of the ceiling or the wall, wherein one or more of the first fasteners comprises an anchor.

4. The enclosure of claim 1 the body of the back member may include an opening through which cabling may pass, wherein the cabling may be coupled to one or more of the electrical components.

5. The enclosure of claim 1 wherein the opening in the finishing bracket is capable of allowing arms and/or a head of a user to pass through the finishing bracket.

6. The enclosure of claim 1 wherein the shell is impact resistant.

7. The enclosure of claim 1 further comprising one or more component brackets capable of coupling with one or more electronic components and the mounting bracket, and wherein at least one of the component brackets is slidably coupled to the mounting bracket such that a position of the at least one component bracket is alterable.

8. The enclosure of claim 1 wherein the mounting bracket further comprises one or more chamfered corners, wherein each chamfered corner comprises:
at least two corners; and wherein each corner is a bend in the outer wall, and
wherein a portion of a top section is removed such that the bend disposes a free edge of a first edge of the top section proximate to a free edge of the second edge of the top section in each of the corners, wherein the top section is disposed on the first side;
and wherein a portion of a bottom section is removed such that the bend disposes a free edge of a first edge of the bottom section proximate to a free edge of the second edge of the bottom section in each of the corners, and wherein the bottom section is disposed on the second side; and
an angled section disposed between at least two of the corners.

9. The enclosure of claim 1 wherein the mounting bracket further comprises two or more slots disposed on an inner surface between the first side and the second side and capable of receiving one or more component brackets, and wherein the inner surfaces of the mounting bracket may comprise a first side and an opposing second side, wherein at least one slot is disposed along at least part of the first side of the inner surfaces, and wherein at least one slot is disposed along at least part of a second side of the inner surfaces;
and wherein the enclosure further comprises:
one or more component brackets capable of coupling with one or more electronic components, wherein each component bracket comprises:
at least one first protrusion; and
at least one second protrusion;
wherein at least one of the first protrusions is configured to be disposed in at least one of the slots disposed along a part of the first side of the inner surface of the mounting bracket and at least one of the second protrusions is configured to be disposed in at least one of the slots disposed along a part of the second side of the inner surfaces to couple the component bracket to the body.

10. An enclosure to house electrical components, the enclosure comprising:
a finishing bracket, wherein the finishing bracket is directly coupleable to at least one of a ceiling or a wall, wherein the finishing bracket comprises:
a first side proximate at least one of the ceiling or the wall upon installation;
a second opposing side; and
an opening disposed through the finishing bracket;
a back member, wherein the back member comprises:
a body, wherein at least a portion of the body is capable of being disposed at least partially through the opening of the finishing bracket;
a flange extending from at least a portion of the body proximate an end of the body of the back member; wherein the flange comprises:
a first side, and wherein the first side of the flange of the back member is coupleable to the second side of the finishing bracket; and
an opposing second side;
a mounting bracket, wherein the mounting bracket comprises:
a first side, wherein the first side is coupleable to a second side of the back member;
a second opposing side;
an outer wall disposed between the first side and the second side;
a second recess disposed in the second side and capable of receiving at least a portion of a second gasket;
one or more openings through the mounting bracket and disposed between the outer wall and the second recess, and wherein each opening is capable of receiving a fastener to couple the mounting bracket to the back member;
wherein the mounting bracket is capable of coupling with one or more electronic components; and
a shell coupled to the second side of the mounting bracket such that the one or more components coupled to the mounting bracket are at least partially enclosed between the shell and the back member and such that the second gasket is at least partially compressed to form a seal between the shell and the mounting frame.

11. The enclosure of claim 10 wherein the mounting bracket further comprises:
a first recess disposed in the first side and capable of receiving at least a portion of a first gasket, wherein coupling the first side of the mounting bracket to the second side of the back member compresses the first gasket to create a first seal between the mounting bracket and the back member, and wherein the one or more openings through the mounting bracket are disposed between the first recess and the outer wall.

12. The enclosure of claim 11 wherein the enclosure is configured to be water resistant upon assembly.

13. The enclosure of claim 10 wherein the second side of the back member comprises a back recess capable of receiving the mounting bracket.

14. The enclosure of claim 10 further comprising one or more component brackets slidably coupleable to the mounting bracket, wherein each of the component brackets is capable of coupling with at least one electronic component.

15. A method of installation of an enclosure, the method comprising:
coupling a finishing bracket to a surface via one or more first fasteners, wherein one or more of the first fasteners are disposed in one or more finishing bracket openings in the finishing bracket, and wherein the surface comprises a ceiling or a wall, and wherein the surface comprises an outer side coupled to the finishing bracket and an inner side proximate an inner area;
creating an orifice in the surface using a second opening in the finishing bracket as a template, wherein the second opening has a size to allow at least one of arms or head of a user to pass through the second opening to the inner area;
disposing a back member at least partially through the second opening in the finishing bracket and the orifice in the surface;
coupling the back member to the finishing member;
coupling one or more component brackets to a mounting bracket coupled to the back member, wherein one or more electrical component are coupled to each of the component brackets;
coupling a shell to the surface by coupling the shell to the mounting bracket, wherein coupling a shell to the mounting bracket compresses at least one of:
a first gasket disposed in a first recess of the mounting bracket or a second gasket disposed in a second recess of the mounting bracket to create a seal between at least one of:
the shell and the mounting bracket or the mounting bracket and the back member.

16. The method of claim 15 wherein coupling a finishing bracket to the surface comprises:
creating a set of first openings in the surface;
disposing each of the first fasteners through one of the finishing bracket openings and through one of the first openings in the set of first openings in the surface such that a first anchor of the first fastener is disposed and retained in the first opening.

17. The method of claim 15 further comprising:
coupling a mounting bracket to the back member; wherein the mounting bracket comprises:
a first side, wherein the first side is coupled to a second side of the back member;
a second opposing side;
an outer wall disposed between the first side and the second side;
one or more inner surfaces disposed between the first recess and an edge of the first side and between the second recess and an edge of the second side;
one or more opposing outer surfaces disposed between the first recess and the outer wall and between the second recess and the outer wall;
one or more openings disposed in at least one of the outer surfaces and through the mounting bracket, and wherein each opening is capable of receiving a fastener to couple the mounting bracket to at least one of the back member or the shell.

18. The method of claim 15 wherein coupling one or more component brackets to the mounting bracket comprises slidably coupling at least one of the component brackets to the mounting bracket.

19. The method of claim 15 further comprising disposing the mounting bracket in a recess of the back member.

20. The method of claim 15 further comprising coupling one or more electrical components to the component bracket.
